(19) United States
(12) Patent Application Publication
(10) Pub. No.: US 2024/0402609 A1
(43) Pub. Date: Dec. 5, 2024

(54) DEVELOPING APPARATUS, SUBSTRATE TREATMENT SYSTEM, AND DEVELOPING METHOD

(71) Applicant: Tokyo Electron Limited, Tokyo (JP)

(72) Inventors: Kenji IIZUKA, Koshi City (JP); Koji USHIMARU, Koshi City (JP); Kazuhiko OOSHIMA, Koshi City (JP); Kei MIYAZAKI, Koshi City (JP); Yuichi TERASHITA, Koshi City (JP); Yukinobu OTSUKA, Koshi City (JP); Katsuhiro IKEDA, Koshi City (JP); Ryohei FUJISE, Koshi City (JP)

(21) Appl. No.: 18/673,751

(22) Filed: May 24, 2024

(30) Foreign Application Priority Data
Jun. 1, 2023 (JP) 2023-090750
Apr. 12, 2024 (JP) 2024-064700

(51) Int. Cl. G03F 7/36; G03F 7/00

(52) U.S. Cl. CPC G03F 7/36; G03F 7/70991

(57) ABSTRACT

A developing apparatus for developing a substrate having a coating film of a metal-containing resist formed thereon, includes: a heating part configured to support and heat the substrate; a chamber configured to cover the heating part and form a treatment space above the heating part; a gas supplier to which a developing gas containing acid is supplied; and a dispersion mechanism configured to disperse the developing gas supplied to the gas supplier and discharge the developing gas to the treatment space from a plurality of discharge ports formed at positions above the heating part.

### CROSS REFERENCE TO RELATED APPLICATIONS

This application is based upon and claims the benefit of priority of the prior Japanese Patent Application No. 2023-90750, filed in Japan on Jun. 1, 2023, and the prior Japanese Patent Application No. 2024-64700, filed in Japan on Apr. 12, 2024, the entire contents of which are incorporated herein by reference.

### TECHNICAL FIELD

This disclosure relates to a developing apparatus, a substrate treatment system, and a developing method.

### BACKGROUND

Japanese Patent Application No. 2022-96081 discloses a developing method of performing a developing treatment on a substrate, including a step of supplying a developing solution containing an organic solvent to the substrate having a metal-containing coating film exposed in a predetermined pattern.

### SUMMARY

An aspect of this disclosure is a developing apparatus for developing a substrate having a coating film of a metal-containing resist formed thereon, the developing apparatus including: a heating part configured to support and heat the substrate; a chamber configured to cover the heating part and form a treatment space above the heating part; a gas supplier to which a developing gas containing acid is supplied; and a dispersion mechanism configured to disperse the developing gas supplied to the gas supplier and discharge the developing gas to the treatment space from a plurality of discharge ports formed at positions above the heating part.

### BRIEF DESCRIPTION OF THE DRAWINGS

FIG. 1 is an explanatory view illustrating the outline of an internal configuration of a coating and developing system as a substrate treatment system including a developing apparatus according to an embodiment.

FIG. 2 is a view illustrating the outline of the internal configuration on the front side of the coating and developing system in FIG. 1.

FIG. 3 is a view illustrating the outline of the internal configuration on the rear side of the coating and developing system in FIG. 1.

FIG. 4 is a longitudinal sectional view schematically illustrating the outline of a configuration of a developing apparatus.

FIG. 5 is a bottom view of an upper chamber.

FIG. 6 is a diagram for explaining a configuration of a gas supply mechanism.

FIG. 7 is a flowchart illustrating main processes of an example of a treatment sequence.

FIG. 8 is a view for explaining another example of a heating part.

FIG. 9 is a view for explaining an example of a raising and lowering pin.

FIG. 10 is a view for explaining another example of a lower chamber.

FIG. 11 is a view for explaining another example of a vaporizer.

### DETAILED DESCRIPTION

In photolithography in a manufacturing process of a semiconductor device or the like, a series of treatments is performed to form a desired pattern of a resist on a substrate such as a semiconductor wafer (hereinafter, referred to as a “wafer”). The series of treatments includes, for example, a resist coating treatment of supplying a resist solution onto the substrate to form a coating film of the resist (hereinafter, a resist film), an exposure treatment of exposing the resist film in a predetermined pattern, a PEB (Post Exposure Bake) treatment of heating the substrate after the exposure for the purpose of promoting a chemical reaction in the exposed resist film, a developing treatment of developing the substrate after the exposure treatment to form a pattern of the resist, and so on.

In the above developing treatment, for example, a developing solution is supplied onto the substrate to form a liquid film of the developing solution on the substrate surface, whereby the substrate is developed. Further, in this case, a cleaning solution such as pure water is then supplied onto the substrate and the substrate is rotated at high speed, whereby the substrate is cleaned in some cases.

Incidentally, with the advances in the exposure technology and the like in recent years, miniaturization of the semiconductor device, namely, miniaturization of the resist pattern further progresses. In a fine resist pattern, if the developing solution or the cleaning solution remains on the substrate in the above-explained developing treatment, a problem may arise. For example, when the developing solution or the cleaning solution remains between patterns, so-called pattern collapse may occur due to the surface tension of the remaining developing solution or cleaning solution.

Further, a chemically amplified resist is conventionally often used as the resist, but a non-chemically amplified metal-containing resist may be used in recent years. This metal-containing resist is expected as a resist more suitable in a case of forming a fine pattern. However, even in the case of using the metal-containing resist, collapse of the pattern, namely, pattern collapse being a type of defect may occur if it is tried to develop the substrate using a treatment solution such as the developing solution to form a fine resist pattern.

Hence, a technique according to this disclosure suppresses the occurrence of a defect such as pattern collapse to obtain an excellent pattern of a metal-containing resist.

Hereinafter, a developing apparatus, a substrate treatment system, and a developing method according to this embodiment will be explained with reference to the drawings. Note that, in this description and the drawings, components having substantially the same functional configurations are denoted by the same reference signs to omit duplicate explanations.

### <Coating and Developing System>

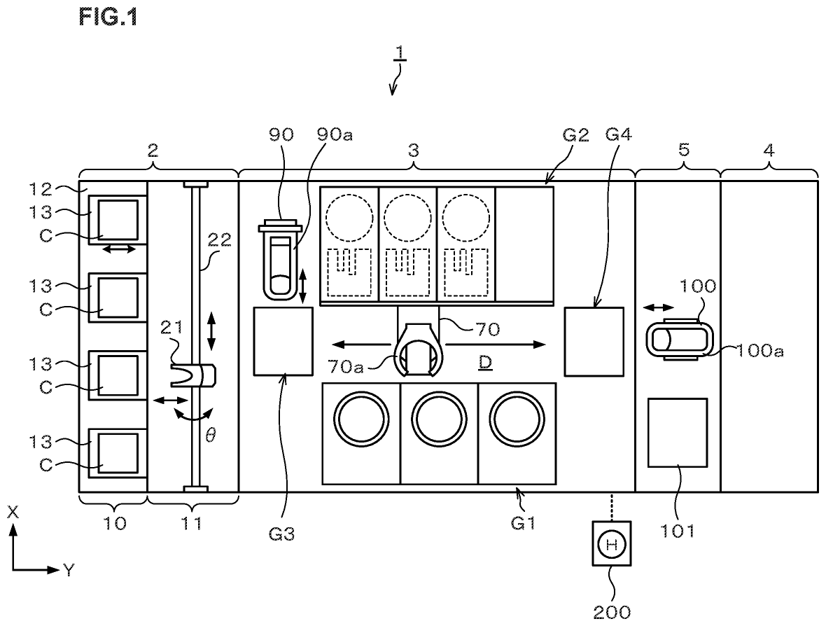

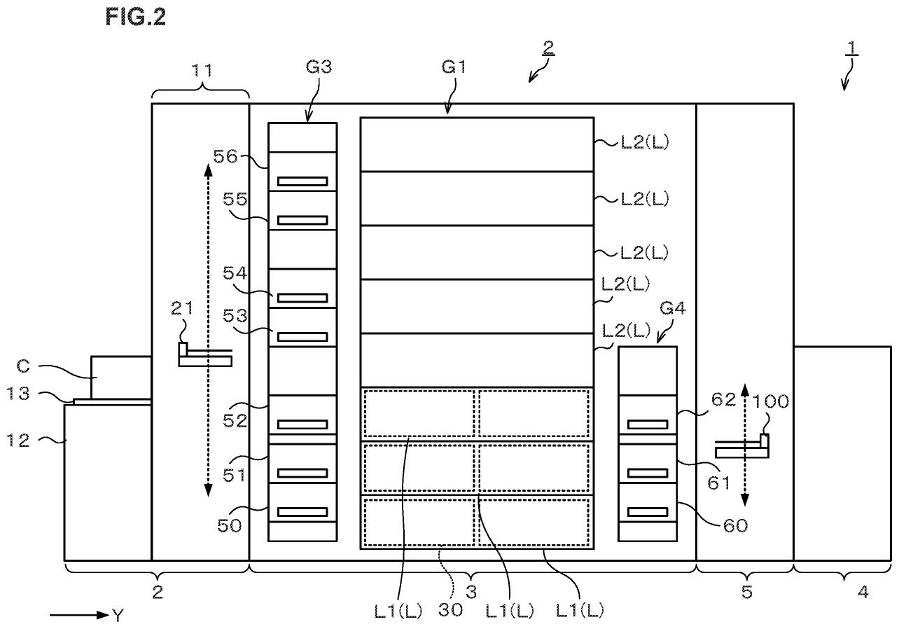

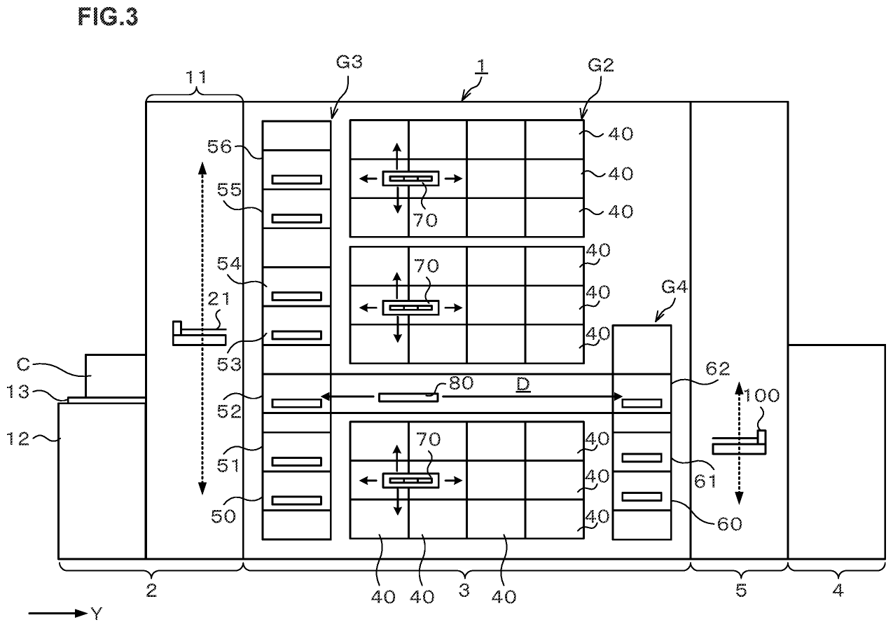

FIG. 1 is an explanatory view illustrating the outline of an internal configuration of a coating and developing system as a substrate treatment system having a developing apparatus according to this embodiment. FIG. 2 and FIG. 3 are views illustrating the outline of the internal configuration on the front side and the rear side of the coating and developing system, respectively.

The coating and developing system 1 in FIG. 1 forms a pattern of a metal-containing resist on a wafer W as a substrate. The metal-containing resist used in the coating and developing system 1 is, for example, a negative type. Note that any metal may be contained in the metal-containing resist and is, for example, tin.

The coating and developing system 1 includes, as illustrated in FIG. 1 to FIG. 3, a cassette station 2 into/out of which a cassette C is transferred from/to the outside, and a treatment station 3 including a plurality of various treatment apparatuses which perform the predetermined treatments such as the developing treatment. The coating and developing system 1 has an interface station 5 which delivers the wafer W to/from an exposure apparatus 4 provided adjacent on a Y-direction positive side (right side in FIG. 1) of the treatment station 3. The above cassette station 2, treatment station 3, and interface station 5 are integrally connected.

The cassette station 2 is divided into, for example, a cassette transfer-in/out section 10 and a wafer transfer section 11. The cassette transfer-in/out section 10 is provided, for example, at an end on a Y-direction negative side (left side in FIG. 1) in the coating and developing system 1. In the cassette transfer-in/out section 10, a cassette stage 12 is provided. On the cassette stage 12, a plurality of, for example, four stage plates 13 are provided. The stage plates 13 are provided side by side in a row in an X-direction (an up-down direction in FIG. 1) being a horizontal direction. On these stage plates 13, cassettes C can be mounted when the cassettes C are transferred to/from the outside of the coating and developing system 1.

In the wafer transfer section 11, a transfer apparatus 21 movable on a transfer path 20 extending in the X-direction (up-down direction in FIG. 1).

The transfer apparatus 21 is movable also in the up-down direction and around a vertical axis (in a θ-direction), and can transfer the wafer W between the cassette C on each of the stage plates 13 and a later-explained delivery apparatus in a third block G3 in the treatment station 3.

In the treatment station 3, a plurality of, for example, four blocks G1, G2, G3, G4 each including various apparatuses are provided. For example, the first block G1 is provided on the front side (X-direction negative side in FIG. 1) in the treatment station 3, and the second block G2 is provided on the rear side (X-direction positive side in FIG. 1) in the treatment station 3. Further, the third block G3 is provided on the cassette station 2 side (Y-direction negative side in FIG. 1) in the treatment station 3, and the fourth block G4 is provided on the interface station 5 side (Y-direction positive side in FIG. 1) in the treatment station 3.

In the first block G1, as illustrated in FIG. 2, a plurality of layers L each including the treatment apparatus are stacked in the up-down direction, namely, the vertical direction. The plurality of stacked layers L have a plurality of layers L1 each including the developing apparatus 30. The number of the developing apparatuses 30 included in the layer L1 may be one, or a plurality of developing apparatuses 30 may be arranged in the horizontal direction in the layer L1. In layers L2 other than the layers L1 in the plurality of stacked layers L, for example, an anti-reflection film forming apparatus and/or a resist coating apparatus are/is included.

Further, the height from the floor surface of the plurality of stacked layers L is equal to or less than the value set in the SEMI standard, and specifically, 2.8 meters or less.

The developing apparatus 30 performs a developing treatment on the wafer W. In other words, the developing apparatus 30 develops the wafer W. Specifically, the developing apparatus 30 develops the wafer W having a coating film of the metal-containing resist formed thereon and subjected to an exposure treatment and a heat treatment after the exposure, namely, a PEB treatment. More specifically, the developing apparatus 30 develops the wafer W having the coating film of the metal-containing resist formed thereon and subjected to the exposure treatment and the PEB treatment, by exposure of the wafer W to a developing gas containing acid as will be explained later. Furthermore specifically, the developing apparatus 30 develops the wafer W by exposing therein the wafer W to a developing gas containing vapor of acid dispersed by a dispersion mechanism composed of a later-explained downstream dispersion plate 311 and the like.

The anti-reflection film forming apparatus forms an anti-reflection film on a lower layer of the coating film of the metal-containing resist of the wafer W.

The resist coating apparatus applies the metal-containing resist to the wafer W to form a coating film of the metal-containing resist, namely, a metal-containing resist film.

In each of the anti-reflection film forming apparatus and the resist coating apparatus, for example, a predetermined treatment solution is applied onto the wafer W by a spin coating method. In the spin coating method, the treatment solution is discharged onto the wafer W, for example, from a discharge nozzle and the wafer W is rotated to diffuse the treatment solution over a front surface of the wafer W.

In the second block G2, thermal treatment apparatuses 40 which perform a heat treatment and a cooling treatment of the wafer W are provided to line up in the up-down direction and the horizontal direction as illustrated in FIG. 3. Note that the number and the arrangement of the thermal treatment apparatuses 40 can also be arbitrarily selected.

In the third block G3, a plurality of delivery apparatuses 50, 51, 52, 53, 54, 55, 56 are provided in order from the bottom. Further, in the fourth block G4, a plurality of delivery apparatuses 60, 61, 62 are provided in order from the bottom.

As illustrated in FIG. 1, in a region surrounded by the first block G1 to the fourth block G4, a wafer transfer region D is formed. In the wafer transfer region D, for example, a transfer apparatus 70 is arranged.

The transfer apparatus 70 has a transfer arm 70a movable, for example, in the Y-direction, a front-rear direction, the θ-direction, and the up-down direction. The transfer apparatus 70 can move in the wafer transfer region D and transfer the wafer W to predetermined apparatuses in the first block G1, the second block G2, the third block G3, and the fourth block G4 therearound. A plurality of the transfer apparatuses 70 are arranged one above the other, for example, as illustrated in FIG. 3, each of which can transfer the wafer W, for example, to a predetermined apparatus at a similar height in each of the blocks G1 to G4.

Further, in the wafer transfer region D, a shuttle transfer apparatus 80 is provided which linearly transfers the wafer W between the third block G3 and the fourth block G4.

The shuttle transfer apparatus 80 can linearly move, for example, in the Y-direction in FIG. 3. The shuttle transfer apparatus 80 can move in the Y-direction while supporting the wafer W to transfer the wafer W between the delivery apparatus 52 in the third block G3 and the delivery apparatus 62 in the fourth block G4.

As illustrated in FIG. 1, a transfer apparatus 90 is provided on the X-direction positive side of the third block G3. The transfer apparatus 90 has a transfer arm 90a movable, for example, in the front-rear direction, the θ-direction, and the up-down direction. The transfer apparatus 90 can move up and down while supporting the wafer W to transfer the wafer W to each of the delivery apparatuses in the third block G3.

In the interface station 5, a transfer apparatus 100 is provided. The transfer apparatus 100 has a transfer arm 100a movable, for example, in the front-rear direction, the e-direction, and the up-down direction. The transfer apparatus 100 can transfer the wafer W to each of the delivery apparatuses in the fourth block G4 and the exposure apparatus 4, for example, while supporting the wafer W by the transfer arm 100a.

In the above coating and developing system 1, at least one control apparatus 200 is provided as illustrated in FIG. 1. The control apparatus 200 processes computer-executable instructions which cause the coating and developing system 1 to execute various processes explained in this disclosure. The control apparatus 200 can be configured to control components of the coating and developing system 1 so as to execute the various processes explained herein. In one embodiment, a part or all of the control apparatus 200 may be included in the coating and developing system 1. The control apparatus 200 may include a processor, a storage, and a communication interface. The control apparatus 200 is realized, for example, by a computer. The processor can be configured to read from the storage a program which provides a logic or routine making it possible to perform various control operations, and execute the read program to thereby perform the various control operations. This program may be stored in the storage in advance, or acquired via a medium when necessary. The acquired program is stored in the storage, read from the storage, and executed by the processor. The medium may be various computer-readable storage media H or may be a communication line connected to a communication interface. The storage medium H may be a transitory one or a non-transitory one. The processor may be a CPU (Central Processing Unit) or may be one or more circuits. The storage may include a RAM (Random Access Memory), a ROM (Read Only Memory), an HDD (Hart Disk Drive), an SSD (Solid State Drive), or a combination of them. The communication interface may communicate with the coating and developing system 1 via a communication line such as a LAN (Local Area Network).

### <Developing Apparatus 30>

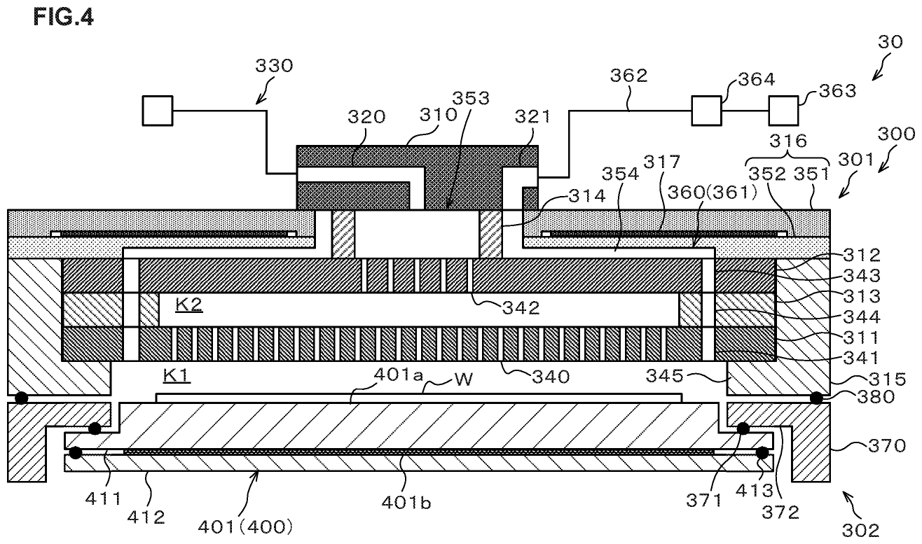

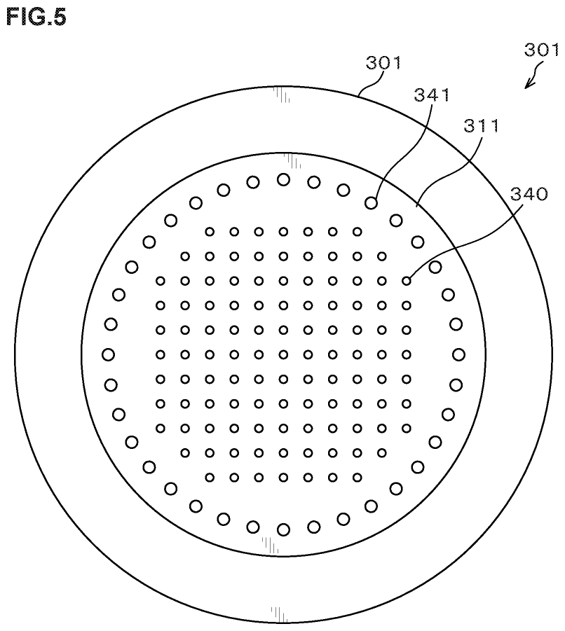

Next, the developing apparatus 30 will be explained. FIG. 4 is a longitudinal sectional view schematically illustrating the outline of a configuration of the developing apparatus 30. FIG. 5 is a bottom view of a later-explained upper chamber 301.

The developing apparatus 30 in FIG. 4 develops the wafer W having the coating film of the metal-containing resist formed thereon and subjected to the exposure treatment and the PEB treatment by exposure of the wafer W to the developing gas containing acid (specifically, the exposure and the heating of the wafer W). The developing apparatus 30 has a chamber 300 which covers a later-explained heating part 400 and forms a treatment space K1 above the heating part 400. The chamber 300 has the upper chamber 301 having the dispersion mechanism composed of the later-explained downstream dispersion plate 311 and the like and located on the upper side, and a lower chamber 302 located on the lower side and forming the treatment space K1 together with the upper chamber 301.

For example, the upper chamber 301 of the upper chamber 301 and the lower chamber 302 is configured to be freely raised and lowered by a raising and lowering mechanism (not illustrated). The raising and lowering mechanism has a driving source (not illustrated) such as a motor which generates a driving force for raising and lowering the upper chamber 301. The raising and lowering mechanism is controlled by the control apparatus 200.

The upper chamber 301 has, for example, a gas supplier 310, the downstream dispersion plate 311, the upstream dispersion plate 312, an intermediate member 313, a connector 314, a side wall part 315, and a top plate part 316.

The gas supplier 310 is a member to which the developing gas containing acid is supplied. Specifically the developing gas contains, for example, vapor of acid. The above acid is, specifically, weak acid and, more specifically, a weak carboxylic acid such as an acetic acid. The “weak acid” in this disclosure means acid having the strength of acid with which the development of the metal-containing resist does not proceed at normal temperature (20° C. to 30° C.), and specifically means acid having a value of an acid dissociation constant (pka) of 4 or more (for example, about 5). Further, the developing gas may contain vapor of an organic solvent. In other words, the developing gas may contain a vaporized substance of a mixed solution of the acid and the organic solvent. The above organic solvent is, for example, propylene glycol monomethyl ether acetate (PGMEA). Further, the developing gas may contain a carrier gas. The carrier gas is, for example, an inert gas such as a nitrogen gas or argon (Ar). The developing gas may be produced only from a single acid such as an acetic acid and the carrier gas without using the organic solvent. In an acid-containing liquid being a raw material of the developing gas, an additive (a component having a function of making the acid easily vaporize) may be mixed. The type of the additive in this case is not particularly limited.

The gas supplier 310 is made of, for example, a fluorocarbon resin having corrosion resistance against corrosive acid.

Inside the gas supplier 310, a flow path 320 through which the supplied developing gas passes is formed. Further, inside the gas supplier 310, an exhaust path 321 through which gas exhausted from the treatment space K1 via a later-explained through hole 341 passes may be formed.

The gas supplier 310 is provided in a manner to close a later-explained opening 353 of the top plate part 316.

Further, to the gas supplier 310, a gas supply mechanism 330 which supplies the developing gas is connected.

The downstream dispersion plate 311 and the upstream dispersion plate 312 constitute the dispersion mechanism. Specifically, the downstream dispersion plate 311, the upstream dispersion plate 312, and the intermediate member 313 constitute the dispersion mechanism, and more specifically, the downstream dispersion plate 311, the upstream dispersion plate 312, the intermediate member 313, and the connector 314 constitute the dispersion mechanism. The dispersion mechanism is a mechanism which disperses the developing gas supplied to the gas supplier 310 in the horizontal direction and discharges the developing gas to the treatment space K1 from a plurality of discharge ports 340 formed at positions above the later-explained heating part 400.

The downstream dispersion plate 311 is a member formed with the plurality of discharge ports 340. The discharge ports 340 are formed to penetrate the downstream dispersion plate 311 in the up-down direction, namely, the vertical direction. Further, the discharge ports 340 are almost uniformly arranged at a portion of the downstream dispersion plate 311 except an outer peripheral portion as illustrated in FIG. 4 and FIG. 5. Note that, in this specification, the outer peripheral portion includes a peripheral edge portion, and the peripheral edge portion includes at least a peripheral edge. The downstream dispersion plate 311 is formed in a plate shape, specifically, formed in a circular plate shape, and more specifically, formed in a circular plate shape larger in diameter than the wafer W.

Further, the downstream dispersion plate 311 has the through hole 341 which penetrates in the up-down direction in a region outside the region where the discharge ports 340 are formed. A plurality of the through holes 341 are provided along a circumferential direction of the downstream dispersion plate 311 corresponding to a circumferential direction of the wafer W (hereinafter, referred to as a wafer circumferential direction) supported on the later-explained heating part 400.

The upstream dispersion plate 312 is provided above the downstream dispersion plate 311 and forms a diffusion space K2 between itself and the downstream dispersion plate 311 as illustrated in FIG. 4. Further, the upstream dispersion plate 312 is formed with a plurality of relay holes 342. The relay holes 342 are formed to penetrate the upstream dispersion plate 312 in the up-down direction. Further, the relay holes 342 are almost uniformly arranged at a central portion of the upstream dispersion plate 312. Note that the relay holes 342 are formed at positions not overlapping with the discharge ports 340 in plan view.

The developing gas supplied to the gas supplier 310 is discharged from the plurality of relay holes 342 to the diffusion space K2. The developing gas discharged to the diffusion space K2 is discharged from the plurality of discharge ports 340 to the treatment space K1.

The upstream dispersion plate 312 is formed in a plate shape, specifically, formed in a circular plate shape, and more specifically, formed in a circular plate shape almost the same in diameter as the downstream dispersion plate 311.

Further, the upstream dispersion plate 312 has through holes 343 at positions corresponding to the through holes 341 of the downstream dispersion plate 311.

The intermediate member 313 is located between the downstream dispersion plate 311 and the upstream dispersion plate 312. Specifically, the intermediate member 313 is located between the peripheral edge portion of the downstream dispersion plate 311 and the peripheral edge portion of the upstream dispersion plate 312. Further, the intermediate member 313 forms the diffusion space K2 together with the downstream dispersion plate 311 and the upstream dispersion plate 312.

The intermediate member 313 is formed in a ring shape and a plate shape in plan view, specifically, formed in a circular ring plate shape, and more specifically, formed in a circular ring plate shape having an outer diameter almost the same as the downstream dispersion plate 311 and having an inner diameter almost the same as the wafer W.

Further, the intermediate member 313 has a through hole 344 at a position corresponding to the through hole 341 of the downstream dispersion plate 311 and the through hole 343 of the upstream dispersion plate 312. The through hole 344 makes the through hole 341 and the through holes 343 communicate with one another.

The connector 314 connects the gas supplier 310 and the relay holes 342. Specifically, the connector 314 connects the gas supplier 310 and the relay holes 342 so that the flow path 320 of the gas supplier 310 and the relay holes 342 communicate with each other. The connector 314 is, for example, a member in a pipe shape (specifically, a circular pipe shape) extending in the up-down direction.

The side wall part 315 is a member which covers the outer peripheral surfaces of the downstream dispersion plate 311, the upstream dispersion plate 312, and the intermediate member 313. Further, the side wall part 315 is provided with a supporter 345 which supports the outer peripheral portions of the downstream dispersion plate 311 and the upstream dispersion plate 312. The inner peripheral surface of the supporter 345 is exposed to the treatment space K1.

The top plate part 316 is a member located above the upstream dispersion plate 312 and is divided into, for example, two, upper and lower, parts, and has an upper first divided member 351 and a lower second divided member 352.

Further, the upper chamber 301 is provided with a heater 317 which heats the top plate part 316. The heater 317 is provided, for example, between the first divided member 351 and the second divided member 352 of the top plate part 316. The first divided member 351 and the second divided member 352 are made of, for example, a nickel-chromium alloy having corrosion resistance against acid. Further, the heater 317 is, for example, a mica heater. By providing the heater 317, the whole upper chamber 301 is heated, so that it is possible to prevent the vapor of acid and the like in the developing gas from re-liquefying from when it is supplied to the gas supplier 310 to when it is discharged to the treatment space K1. Further, by providing the heater 317, the downstream dispersion plate 311 and the like are also heated, so that it is possible to prevent a sublimate produced from the metal-containing resist film during the development from being cooled and adhering to the downstream dispersion plate 311 and the like.

At the center in plan view of the top plate part 316, the opening 353 is formed. The opening 353 is formed, for example, in a manner to penetrate the first divided member 351 and the second divided member 352.

Further, the top plate part 316 is in contact with the gas supplier 310. For example, the first divided member 351 of the top plate part 316 is in contact with the gas supplier 310.

Further, the top plate part 316 is in contact with a later-explained peripheral exhaust path 361. For example, the second divided member 352 of the top plate part 316 forms a horizontal exhaust path 354, which makes the gas exhausted from the treatment space K1 horizontally flow, between itself and the upstream dispersion plate 312, and the horizontal exhaust path 354 forms a part of the peripheral exhaust path.

Further, the upper chamber 301 is provided with a peripheral exhauster 360. The peripheral exhauster 360 exhausts the treatment space K1 from the peripheral edge portion side of the wafer W supported on the later-explained heating part 400 in plan view. The peripheral exhauster 360 has an exhaust port opening to the treatment space K1. For example, the lower end of the through hole 341 of the above-explained downstream dispersion plate 311 forms the above exhaust port. The peripheral exhauster 360 exhausts the treatment space K1 via the exhaust port.

The peripheral exhauster 360 has the peripheral exhaust path 361 extending from the exhaust port. The peripheral exhaust path 361 is composed of, for example, the through hole 341, the through hole 344, the through hole 343, the horizontal exhaust path 354, the exhaust path 321, and so on. In other words, each of the through hole 341, the through hole 344, the through hole 343, the horizontal exhaust path 354, and the exhaust path 321 forms a part of the peripheral exhaust path 361. To the peripheral exhaust path 361, an exhaust apparatus 363 such as a vacuum pump is connected via an exhaust pipe 362. The exhaust pipe 362 is provided with an exhaust equipment group 364 having a valve and so on which regulate the exhaust rate.

The exhaust apparatus 363 and the exhaust equipment group 364 are controlled by the control apparatus 200. Note that the exhaust pipe 362 may be provided with a tank for gas-liquid separation.

The lower chamber 302 has a side wall part (also referred to as a lower side wall part) 370. The side wall part 370 covers the outer peripheral portion of the later-explained heating part 400 and faces the side wall part (also referred to as an upper side wall part) 315 of the upper chamber 301.

A gap between the lower chamber 302 and the heating part 400 is sealed with an O-ring 371 made of resin. Specifically, the side wall part 370 of the lower chamber 302 has an annular part 372 projecting to the inner peripheral side, and a gap between the lower surface of the annular part 372 and the upper surface of a peripheral edge portion of a later-explained plate-shaped member 411 of the heating part 400 is sealed with the O-ring 371.

The downstream dispersion plate 311, the upstream dispersion plate 312, the intermediate member 313, the connector 314, and the side wall part 315 of the above-mentioned upper chamber 301, and the side wall part 370 of the lower chamber 302 are formed of, for example, a nickel-chromium alloy, silicon, or a silicon compound having corrosion resistance against acid. The nickel-chromium alloy having corrosion resistance against acid is, for example, Hastelloy. Besides, the silicon compound having corrosion resistance against acid is, for example, a ceramic, preferably the one containing no metal (element), and specifically, for example, silicon carbide (SiC), silicon dioxide (SiO₂) or the like. Further, the ceramic having corrosion resistance against acid is preferably high in heat conductivity than stainless steel (specifically, SUS 304). The heat conductivity of, for example, SiC is higher than SUS304. The downstream dispersion plate 311, the upstream dispersion plate 312, and the intermediate member 313, and the side wall part 315 which is in contact (or may be in contact) with their outer peripheral surfaces are preferably made of the same material. This can prevent breakage of at least one of the downstream dispersion plate 311, the upstream dispersion plate 312, the intermediate member 313, and the side wall part 315 due to the thermal expansion difference between the downstream dispersion plate 311, the upstream dispersion plate 312, and the intermediate member 313, and, the side wall part 315. In addition, it is possible to prevent the communication between the through hole 341 and the through hole 343 via the through hole 344 from being hindered due to the thermal expansion difference, namely, prevent the peripheral exhaust path 361 from being blocked due to the thermal expansion difference.

Further, an inner peripheral end of a joint between the upper chamber 301 and the lower chamber 302 at an outer periphery, namely, the outer side of the treatment space K1 is located on a lower side than the lower end of the through hole 341 forming the exhaust port of the peripheral exhauster 360. The joint is formed, specifically, between the lower surface of the side wall part 315 of the upper chamber 301 and the upper surface of the side wall part 370 of the lower chamber 302. An O-ring 380 sealing the joint may be provided.

Note that the O-ring 371 and the O-ring 380 are made of, for example, a resin, and specifically, made of a fluorocarbon resin having corrosion resistance against acid.

Further, the developing apparatus 30 includes the heating part 400 which supports and heats the wafer W.

The heating part 400 has a hot plate 401. The hot plate 401 has a mounting surface 401a on which the wafer W is mounted, and a heater pattern 401b. The heater pattern 401b is made of, for example, metal.

The hot plate 401 further has plate-shaped members 411, 412 holding the heater pattern 401b from top and bottom. The plate-shaped member 411, 412 is formed, for example, in a circular plate shape. The upper plate-shaped member 411 has the mounting surface 401a. Specifically, the upper surface at a central portion of the upper plate-shaped member 411 constitutes the mounting surface 401a. In one embodiment, the plate-shaped member 411 is formed such that the position of the upper surface is higher at the central portion than at the peripheral portion. Further, the plate-shaped members 411, 412 are made of ceramic, and specifically made of SiC.

Further, the hot plate 401 has an elastic O-ring 413 as a sealing member which seals a gap between the plate-shaped members 411 and 412 at the outer periphery, namely, the outside of the heater pattern 401b. The O-ring 413 is made of, for example, a resin, and specifically, made of a fluorocarbon resin. The plate-shaped members 411, 412 are fixed in a state of holding the O-ring 413 therebetween.

The temperature of the hot plate 401 is adjusted by control of an energization amount to the heater pattern 401b, for example, by the control apparatus 200, whereby the wafer W mounted on the hot plate 401 is heated to a predetermined temperature.

The hot plate 401 may be configured to be able to perform heating so that the temperature of the wafer W differs in a radial direction of the wafer W.

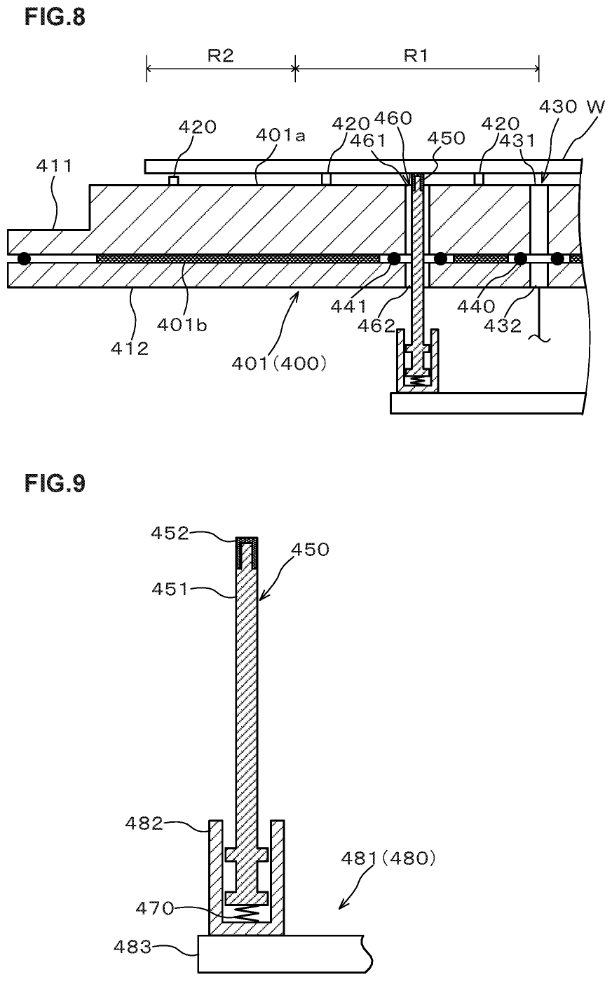

Further, the heating part 400 may have a plurality of protrusions (see a reference sign 420 in FIG. 8 explained later) provided in a manner to protrude from the mounting surface 401a and supporting the wafer W, and the protrusions may be interposed between the mounting surface 401a and the wafer W so as to prevent the wafer W from coming into direct contact with the mounting surface 401a. This makes it possible to prevent a foreign substance from adhering to the mounting surface 401a in contact with the wafer W and prevent the wafer W from being contaminated with a foreign substance on the mounting surface 401a. The plurality of protrusions are provided at, for example, the following positions.

The mounting surface 401 a is partitioned into a plurality of regions (see reference signs R1, R2 in FIG. 8) along a radial direction of the mounting surface 401a (namely, the radial direction of the wafer W mounted on the mounting surface 401a), and the protrusion is provided in each of the regions. Specifically, the protrusion is provided in each of a plurality of (three or more) portions different from each other in position relating to the circumferential direction (namely, the wafer circumferential direction) of the mounting surface 401a in each region.

### <Gas Supply Mechanism 330>

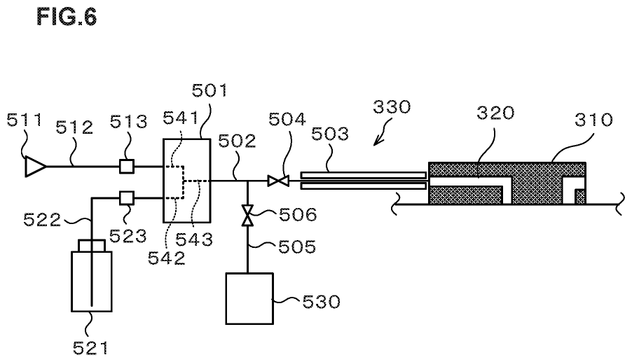

Next, the gas supply mechanism 330 will be explained. FIG. 6 is a diagram for explaining a configuration of the gas supply mechanism 330.

The gas supply mechanism 330 has a vaporizer 501 which vaporizes the mixed solution of the acid and the organic solvent to produce the developing gas, for example, as illustrated in FIG. 6. To the vaporizer 501, one end of a supply path 502 is connected. Another end of the supply path 502 is connected to the gas supplier 310, and specifically, connected to the flow path 320 of the gas supplier 310. The supply path 502 is made of a fluorocarbon resin having corrosion resistance against acid. Further, the supply path 502 is provided with a heater 503 which heats the supply path 502. The heater 503 is formed, for example, in a tape shape, namely, is a tape heater which is used wound around the supply path 502.

The heater 503 is provided at least on the downstream side of the supply path 502. On the upstream of a portion of the supply path 502 where the heater 503 is provided, an opening/closing valve 504 is provided which controls distribution of the developing gas in the supply path 502. The opening/closing valve 504 is controlled by the control apparatus 200.

To the vaporizer 501, a supply source 511 of an inert gas is connected via a gas supply path 512. The gas supply path 512 is provided with a supply equipment group 513 including an opening/closing valve for controlling distribution of the inert gas in the gas supply path 512, a flow regulating valve for regulating the flow rate of the inert gas, and so on. The supply equipment group 513 is controlled by the control apparatus 200.

Further, to the vaporizer 501, a tank 521 which stores the mixed solution of the acid and the organic solvent is connected via a solution supply path 522. The solution supply path 522 is provided with a supply equipment group 523 including an opening/closing valve for controlling distribution of the mixed solution in the solution supply path 522, a flow regulating valve for regulating the flow rate of the mixed solution, and so on. The supply equipment group 523 is controlled by the control apparatus 200. Note that the supply of the mixed solution of the acid and the organic solvent is not limited to that by the tank 521 but may also be that, for example, by a configuration in which a supply pipe of the mixed solution from a facility in a factory, for example, provided with the developing apparatus 30 is connected to the solution supply path 522.

Further, to the supply path 502, a branch path 505 is connected. Specifically, one end of the branch path 505 is connected to a point between the vaporizer 501 and the opening/closing valve 504 on the supply path 502. Another end of the branch path 505 is connected to a drain tank 530. The branch path 505 is provide with an opening/closing valve 506 which controls distribution of the developing gas in the branch path 505. The opening/closing valve 506 is controlled by the control apparatus 200.

As explained later, the developing gas produced by the vaporizer 501 is not supplied to the gas supplier 310 but may be made to flow toward the branch path 505. The vapor contained in the developing gas made to flow toward the branch path 505 is cooled to be re-liquefied, and stored in the drain tank 530.

Further, the vaporizer 501 has a flow path 541 through which an inert gas flows, a flow path 542 through which the mixed solution flows, and a flow path 543 through which a mixed fluid obtained by mixing the inert gas and the mixed solution flows and in which the mixed fluid is heated and the mixed solution is vaporized.

Further, the vaporizer 501 has an inner wall surface of the flow path through which (liquid of) acid or vapor of acid flows, which is made of a nickel-chromium alloy, silicon, or a silicon compound having corrosion resistance against acid. Specifically, in the vaporizer 501, for example, members forming the flow paths 541, 542, 543 are made of a nickel-chromium alloy, silicon, or a silicon compound.

### Example of a Treatment Sequence

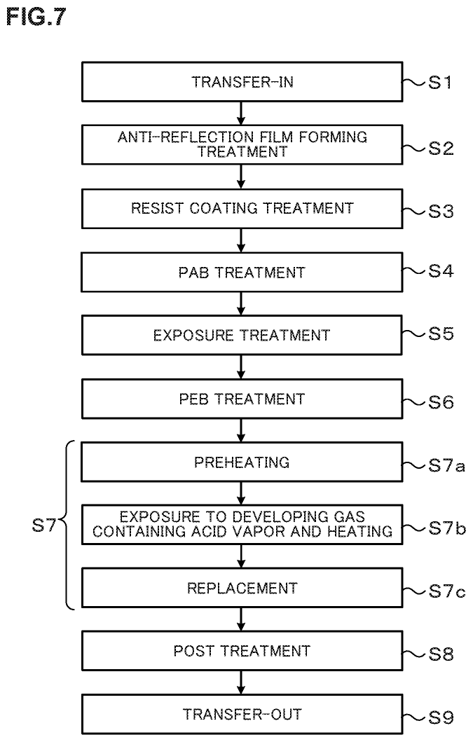

Next, an example of a treatment sequence executed by the coating and developing system 1 will be explained. FIG. 7 is a flowchart illustrating main processes of an example of the treatment sequence. Note that the following processes are executed under the control of the control apparatus 200 based on the program stored in the above-explained program storage (not illustrated).

### (Step S1)

First, the wafer W is transferred to the inside of the coating and developing system 1.

Specifically, the cassette C housing a plurality of wafers W is transferred into the cassette station 2 of the coating and developing system 1 and mounted on the stage plate 13. Then, the wafers W in the cassette C are successively taken out by the transfer apparatus 21, transferred to the inside of the wafer transfer section 11, and transferred to the delivery apparatus 53 in the third block G3 in the treatment station 3.

### (Step S2)

Next, the anti-reflection film forming treatment is performed on the wafer W to form an anti-reflection film on the wafer W.

Specifically, for example, the wafer W is transferred by the transfer apparatus 70 to the anti-reflection film forming apparatus in the layer L2, in which an anti-reflection film material is applied by rotation onto the front surface of the wafer W to form an anti-reflection film as a base film for the metal-containing resist in a manner to cover the front surface of the wafer W.

### (Step S3)

Next, the resist coating treatment is performed on the wafer W to form a metal-containing resist film on the wafer W.

Specifically, the wafer W is transferred by the transfer apparatus 70 to the resist coating apparatus in the layer L2, in which the metal-containing resist is applied by rotation onto the front surface of the wafer W to form a negative metal-containing resist film in a manner to cover the anti-reflection film as the base film.

### (Step S4)

Subsequently, the PAB treatment is performed on the wafer W.

Specifically, the wafer W is transferred by the transfer apparatus 70 to the thermal treatment apparatus 40 for the PAB treatment and subjected to the PAB treatment. The wafer W is then transferred by the transfer apparatus 70 to the delivery apparatus 56 in the third block G3, then transferred by the transfer apparatus 90 to the delivery apparatus 52, and transferred by the shuttle transfer apparatus 80 to the delivery apparatus 62 in the fourth block G4.

### (Step S5)

Next, the exposure treatment is performed on the wafer W.

Specifically, the wafer W is transferred by the transfer apparatus 100 in the interface station 5 to the exposure apparatus 4, in which the resist film on the wafer W is exposed in a predetermined pattern using EUV light. The wafer W is then transferred by the transfer apparatus 100 to the delivery apparatus 60 in the fourth block G4.

### (Step S6)

Next, the PEB treatment is performed on the wafer W.

Specifically, the wafer W is transferred by the transfer apparatus 70 to thermal treatment apparatus 40 for the PEB treatment and subjected to the PEB treatment.

### (Step S7)

Subsequently, the wafer W is developed.

Specifically, following Steps Sa, S7b, S7c are performed.

### (Step S7a)

At this process, the wafer W is preheated before development.

Specifically, the wafer W is first moved by the transfer apparatus 70 to a position between the upper chamber 301 in a raised state and the heating part 400. Thereafter, the wafer W is mounted and supported on the mounting surface 401a of the hot plate 401 via raising and lowering pins (not illustrated). In the case where the above-mentioned protrusions are provided at the heating part 400, the wafer W is supported by the plurality of protrusions, namely, supported on the mounting surface 401a via the plurality of protrusions. Note that at this stage, the hot plate 401 has been regulated to a predetermined temperature. Further, the upper chamber 301 is lowered and the upper chamber 301 and the lower chamber 302 define the treatment space K1.

After a lapse of a predetermined time after the wafer W is mounted on the hot plate 401, this Step S7a ends.

Also during the preheating of the wafer W at this Step S7a, the supply of the developing gas from the vaporizer 501 is performed as during the development of the wafer W at later-explained Step S7b.

Specifically, also during the preheating of the wafer W at this Step S7a, the supply of the inert gas from the supply source 511 to the vaporizer 501, the supply of the mixed solution from the tank 521 to the vaporizer 501, the vaporization of the mixed solution in the vaporizer 501, and the supply of the developing gas containing the vaporized substance of the mixed solution from the vaporizer 501 to the supply path 502 are performed.

However, during the preheating of the wafer W at this Step S7a, the developing gas supplied from the vaporizer 501 is not made to flow to the gas supplier 310 but is made to flow to the branch path 505.

Specifically, the opening/closing valve 504 provided on the supply path 502 is brought into a closed state, the opening/closing valve 506 provided on the branch path 505 is brought into an open state, and the developing gas supplied from the vaporizer 501 is made to flow through the branch path 505 toward the drain tank 530.

Note that during this Step S7a, the inert gas may be supplied to the gas supplier 310 and the inert gas may be discharged to the treatment space K1. Specifically, at this Step S7a, after the upper chamber 301 is lowered to define the treatment space K1, the inert gas may be supplied to the gas supplier 310 and the inert gas may be discharged to the treatment space K1. This can prevent the metal-containing resist film on the wafer W from unnecessarily reacting with the moisture or the like in the treatment space K1. Further, the inert gas to be supplied to the gas supplier 310 may be the one heated by the heater 503. This can prevent the wafer W from being cooled by the inert gas supplied during the preheating, resulting in a reduction in time required for heating the wafer W up to a predetermined temperature.

Further, during this Step S7a, exhaust by the peripheral exhauster 360 is performed.

Specifically, at this Step S7a, after the upper chamber 301 is lowered to define the treatment space K1, the exhaust by the peripheral exhauster 360 is performed. In this event, the exhaust by the peripheral exhauster 360 is performed so that the pressure in the treatment space K1 becomes negative pressure with respect to the pressure outside the chamber 300. This is the same also in the case where the inert gas is supplied to the treatment space K1. This can prevent the sublimate from the metal-containing resist film from leaking to the outside of the chamber 300 during the preheating of the wafer W.

In the case of performing the preheating of the wafer W at this Step S7a, the development can be performed more uniformly and stably within the plane of the wafer W, as compared with the case of performing the development using the developing gas from a low temperature state of the wafer W without performing the preheating of the wafer W.

### (Step S7b)

After Step S7a, the wafer W supported on the heating part 400 is heated and the developing gas is discharged to the treatment space K1, whereby the wafer W is developed.

Specifically, the wafer W supported on the heating part 400 is heated, and the developing gas supplied from the vaporizer 501 to the gas supplier 310 via the supply path 502 is discharged to the treatment space K1, whereby the wafer W is developed.

More specifically, the state where the wafer W is supported on the hot plate 401 is continued. Further, if the inert gas has been being supplied to the gas supplier 310 during Step S7a, the supply is stopped. Further, the opening/closing valve 504 provided on the supply path 502 is brought into an open state, and the opening/closing valve 506 provided on the branch path 505 is brought into a closed state, and the developing gas from the vaporizer 501 made to flow to the branch path 505 is made to flow through the supply path 502 toward the gas supplier 310. As explained above, the supply of the developing gas from the vaporizer 501 is continued without interruption between Step S7a and Step S7b. The developing gas from the vaporizer 501 reaching the gas supplier 310 is discharged from the discharge ports 340 toward the wafer W in the treatment space K1. This exposes the wafer W to an atmosphere of the developing gas containing acid in the treatment space K1. When the negative metal-containing resist film on the wafer W is exposed to the atmosphere, an unexposed portion reacts with, for example, the vapor of the acid in the developing gas and thereby lowers in molecular weight. Then, the unexposed portion which has lowered in molecular weight by the reaction with the vapor of acid of the negative metal-containing resist film on the wafer W sublimes by heat, whereby a pattern of the metal-containing resist is formed. For example, in the case where the acid is an acetic acid and the metal-containing resist film contains tin as a metal, tin acetate sublimates.

Further, during this Step S7b, the exhaust by the peripheral exhauster 360 is performed continuously from Step S7a. Specifically, the exhaust by the peripheral exhauster 360 is performed continuously from Step S7a so that the pressure in the treatment space K1 becomes negative pressure with respect to the pressure outside the chamber 300. This can prevent the sublimate from the metal-containing resist film from leaking to the outside of the chamber 300 during the development at this Step S7b.

Note that after a lapse of a predetermined time after the start of the discharge of the developing gas to the treatment space K1, the supply of the developing gas to the treatment space K1 is stopped, specifically, the opening/closing valve 504 provided on the supply path 502 is brought into a closed state, and this Step S7b ends.

### (Step S7c)

After Step S7b, the atmosphere of the developing gas in the treatment space K1 is replaced with the inert gas.

Specifically, for example, the inert gas from the supply source 511 is supplied to the gas supplier 310 via a bypass path (not illustrated), and the inert gas is discharged to the treatment space K1. Also during the replacement with the inert gas, the exhaust by the peripheral exhauster 360 is performed. Specifically, also during the replacement, the exhaust by the peripheral exhauster 360 is performed so that the pressure in the treatment space K1 becomes negative pressure with respect to the pressure outside the chamber 300. This can prevent the sublimate from the metal-containing resist film from leaking to the outside of the chamber 300 during the replacement.

Upon completion of the replacement with the inert gas after a lapse of a predetermined time after the start of the discharge of the inert gas, stop of the discharge of the inert gas to the treatment space K1, stop of the exhaust by the peripheral exhauster 360, and raising of the upper chamber 301 are performed, and the wafer W is delivered to the transfer apparatus 70 via the raising and lowering pins (not illustrated). The wafer W is then transferred by the transfer apparatus 70 to the outside of the developing apparatus 30.

Step S7c can prevent the developing gas from leaking to the outside of the chamber 300 when the chamber 300 is opened, namely, the upper chamber 301 is raised at the transfer of the wafer W to the outside of the chamber 300.

Note that the discharge of the inert gas to the treatment space K1 at this Step S7c may also accomplish the purpose of completing the reaction between the developing gas and the metal-containing resist film. Besides, the inert gas discharged to the treatment space K1 at this Step S7c may also be heated by the heater 503.

### (Step S8)

After the development, the POST treatment is performed on the wafer W.

Specifically, the wafer W is transferred to the thermal treatment apparatus 40 for the POST treatment and subjected to the POST treatment. This Step S8 may be omitted.

### (Step S9)

Then, the wafer W is transferred out of the coating and developing system 1.

Specifically, the wafer W is returned to the cassette C by a procedure reverse to that at Step S1.

With this, the serial treatment sequence is completed.

### Main Operations and Effects of this Embodiment

As explained above, in this embodiment, the wafer W having the coating film of the metal-containing resist formed thereon and supported on the heating part 400 is heated, and the developing gas containing acid is discharged to the treatment space to develop the wafer W. In other words, in this embodiment, a portion to be removed by the development of the metal-containing resist film is removed by the developing gas containing acid without using the treatment solution such as the developing solution, the cleaning solution, or the like, to form the pattern of the metal-containing resist. This never causes the occurrence of the pattern collapse due to the surface tension of the treatment solution. Therefore, according to this example, the pattern collapse of the metal-containing resist can be prevented, so that an excellent pattern of the metal-containing resist can be obtained.

Further, in this embodiment, the developing gas supplied to the gas supplier 310 is dispersed (specifically, dispersed in the horizontal direction) and then discharged to the treatment space K1 from the plurality of discharge ports 340 formed at positions above the heating part 400. Therefore, the state of the developing gas such as the density of the developing gas in the treatment space K1 can be made more uniform within the wafer plane near the wafer W, as compared with the case of supplying the developing gas without dispersion. Accordingly, the developing result using the developing gas can be made more uniform within the wafer plane.

Further, in this embodiment, no plasma is used during the development, namely, the portion to be removed by the development of the metal-containing resist film is removed without using plasma. In a case of supplying plasma from an upper part of the treatment space toward the wafer at a lower part, the treatment space needs to be made larger in the up-down direction, namely, the vertical direction in order to adjust the state of ions and radicals in the plasma. In contrast to this, no plasma is used during the development in this embodiment, and therefore the treatment space K1 does not need to be made larger in the up-down direction. Therefore, according to this embodiment, many layers each including the developing apparatus 30 can be staled within the height at which the operation can be safely performed. Therefore, according to this embodiment, the throughput of the development is easy to improve.

Specifically, this is as follows. The SEMI standard is set as a unified standard from the viewpoint of the improvement in productivity and safety, and recommendation values are set for the apparatus sizes such as the apparatus height and so on in the SEMI standard. Specifically, a height of 2.8 m from the floor surface is the recommendation value of the apparatus height in SEMI E72. The installation of the treatment apparatus within a range of the recommendation value of the apparatus height is one factor for improving the throughput, namely, the productivity. Further, considering the productivity and the safety, it is desired to install the developing apparatus 30 which performs the treatment and is an object of the work within the height of 2.8 m from the floor surface indicated in SEMI E72. The developing apparatus 30 according to this embodiment can be stacked and installed in a plurality of layers within the apparatus height (height of the coating and developing system 1) set in the SEMI standard. Specifically, a large number of the developing apparatuses 30, such as not two or three but four to eight developing apparatuses 30 (in a case where the height of the developing apparatus 30 corresponds to that of one thermal treatment apparatus 40) can be stacked and installed, for example, in one coating and developing system 1. Note that even if a layer including another treatment apparatus such as a coating film forming apparatus is provided above or below the layer L1 including the developing apparatus 30, the number of the developing apparatuses 30 equivalent to the above can be stacked and installed within the range of the height set in SEMI E72.

Further, in this embodiment, the plate-shaped members 411, 412 which constitute the hot plate 401 and hold the heater pattern 401b from top and bottom are made of ceramic having corrosion resistance against acid. Therefore, it is possible to prevent the plate-shaped members 411, 412 from being damaged by the developing gas containing acid. Specifically, it is possible to prevent the construction material of the plate-shaped members 411, 412 from being eluted by the developing gas and contaminating the inside of the chamber 300 and the wafer W. Note that if the construction material of the plate-shaped members 411, 412 contains metal, the metal may affect the device characteristics, and therefore the ceramic constituting the plate-shaped members 411, 412 is preferably the one containing no metal (element) such as SiC.

Further, since the gap between the plate-shaped members 411 and 412 at the outer periphery, namely, the outside of the heater pattern 401b is sealed with the O-ring 413, it is possible to prevent the developing gas containing the vapor of acid from going around the plate-shaped member 411 and reaching the heater pattern 401b. Accordingly, it is possible to prevent the heater pattern 401b from being damaged by the developing gas.

Furthermore, the gap between the plate-shaped member 411 and the annular part 372 of the lower chamber 302 is sealed with the O-ring 371. Therefore, it is possible to surely prevent the developing gas containing the vapor of acid from going around the plate-shaped member 411 and reaching the heater pattern 401b. Accordingly, it is possible to more surely prevent the heater pattern 401b from being damaged by the developing gas.

Further, the plate-shaped members 411 and 412 fixed to each other are formed of the same material, so that it is possible to prevent the plate-shaped members 411 and 412 from breaking due to the thermal expansion difference between the plate-shaped members 411 and 412.

Further, the O-rings 413, 371 are made of a fluorocarbon resin having corrosion resistance against acid, so that it is possible to prevent the O-rings 413, 371 from being damaged by the developing gas containing the vapor of acid.

As explained above, in this embodiment, the through hole 344 of the intermediate member 313 forms a part of the peripheral exhaust path 361. In other words, the intermediate member 313 forming the diffusion space K2 forms a part of the peripheral exhaust path 361. Therefore, it is possible to bring the supply path of the developing gas including the diffusion space K2 close to the peripheral exhaust path 361 while accurately forming the peripheral exhaust path 361 at a desired position, and thereby downsize the developing apparatus 30, specifically, downsize the upper chamber 301.

Further, in this embodiment, the inner peripheral end of the joint between the upper chamber 301 and the lower chamber 302 is located on a lower side than the lower end of the through hole 341 forming the exhaust port of the peripheral exhauster 360. Therefore, the developing gas containing the vapor of acid is unlikely to flow toward the joint. Accordingly, it is possible to prevent the developing gas (especially, the vapor of acid) from leaking to the outside of the chamber 300 through the joint.

Further, in this embodiment, the top plate part 316 heated by the heater 317 is in contact with the gas supplier 310. Therefore, it is easy to keep warm the developing gas flowing through the gas supplier 310. Accordingly, it is possible to efficiently prevent the vapor of the acid and solvent in the developing gas from re-liquefying from when it is supplied to the gas supplier 310 to when it is discharged to the treatment space K1.

Furthermore, in this embodiment, the top plate part 316 is in contact also with the peripheral exhaust path 361. Therefore, it is easy to keep warm the exhaust gas from the treatment space K1 flowing through the peripheral exhaust path 361. Accordingly, it is possible to efficiently prevent a product produced during the development contained in the exhaust gas from being cooled and adhering to the inner wall surface and the like of the peripheral exhaust path 361.

In this embodiment, the downstream dispersion plate 311, the upstream dispersion plate 312, the intermediate member 313, the connector 314, and the side wall part 315 of the upper chamber 301, and the side wall part 370 of the lower chamber 302 are formed of, for example, a nickel-chromium alloy or ceramic having corrosion resistance against acid. Therefore, it is possible to prevent the downstream dispersion plate 311, the upstream dispersion plate 312, the intermediate member 313, the connector 314, the side wall part 315, and the side wall part 370 from being damaged by the developing gas containing the vapor of acid. Specifically, it is possible to prevent the construction material of the upstream dispersion plate 312, the intermediate member 313, the connector 314, the side wall part 315, and the side wall part 370 from being eluted by the developing gas and contaminating the inside of the chamber 300 and the wafer W.

Further, in this embodiment, the inner wall surface of the flow path through which acid or vapor of acid flows in the vaporizer 501 is formed of a nickel-chromium alloy or ceramic having corrosion resistance against acid. Therefore, it is possible to prevent the inner wall surface from being damaged by the developing gas containing the vapor of acid. Specifically, it is possible to prevent the construction material of the inner wall surface from eluting and contaminating the inside of the chamber 300 and the wafer W.

Further, in this embodiment, at the preheating process of the wafer W at Step S7a followed by Step S7b, the developing gas is supplied from the vaporizer 501, and the developing gas from the vaporizer 501 is not made to flow to the gas supplier 310 but is made to flow to the branch path 505. Therefore, directly after the start of the development at Step S7b, the state of the developing gas supplied from the vaporizer 501 and discharged to the treatment space K1 becomes stable. Therefore, it is possible to prevent the developing result from varying between the wafers W and within the plane of the wafer W.

Further, in this embodiment, the supply path 502 is made of a fluorocarbon resin having corrosion resistance against acid. Therefore, it is possible to prevent the supply path 502 from being damaged by the developing gas containing the vapor of acid. Specifically, it is possible to prevent the construction material of the supply path 502 from being eluted by the developing gas and contaminating the inside of the chamber 300 and the wafer W. Further, the supply path 502 is heated by the heater 503, so that it is possible to prevent the vapor of the acid and solvent in the developing gas from re-liquefying until it is discharged to the treatment space K1.

<Requirement in the Case where the Developing Gas Contains Vapor (Gas) of Acetic Acid and Organic Solvent>

### (1. Requirement of Spontaneous Ignition Point)

The development by the mixed gas of acetic acid and organic solvent cannot be performed in terms of safety under the condition that the temperature in the treatment space K1, namely, the treatment temperature exceeds a spontaneous ignition temperature of the acetic acid or the organic solvent. Besides, the spontaneous ignition temperature of the organic solvent is generally lower than the spontaneous ignition temperature (485° C.) of the acetic acid. For example, the spontaneous ignition temperature of PGMEA is 272° C. Therefore, the treatment temperature at the development by the mixed gas of the acetic acid and organic solvent is limited to the spontaneous ignition temperature of the organic solvent. Accordingly, in the case where the development by the mixed gas of the acetic acid and organic solvent is preferable in terms of the developing performance, an organic solvent high in spontaneous ignition temperature and close to that of the acetic acid is preferable.

### (2. Requirement of Ease of Vaporization)

In the case of vaporizing the mixed solution of the acetic acid and the organic solvent in the vaporizer to produce the mixed gas of the acetic acid and the organic solvent as the developing gas, if the acetic acid and the organic solvent are different in ease of vaporization, the concentration of the mixed solution in the vaporizer changes, resulting in that the acetic acid gas concentration in the developing gas to be produced also changes. This makes it difficult to keep constant the acetic acid gas concentration in the developing gas to be supplied to the treatment space K1. Therefore, the acetic acid and the organic solvent are preferably close in ease of vaporization. Examples of the standard of the ease of vaporization of liquid are a boiling point and a vapor pressure. Liquid is less likely to vaporize as the boiling point is higher, and is more likely to vaporize as the boiling point is lower. Besides, liquid is more likely to vaporize as the vapor pressure is higher, and is less likely to vaporize as the vapor pressure is lower. For mixed fluids, the ease of vaporization is proportional to the mole fraction, and the mole fraction is determined from the molecular weight. In other words, the molecular weight is also a relevant parameter for ease of vaporization.

Because of the above two requirements, in the case of producing the mixed gas from the mixed solution of the acetic acid and the organic solvent, it is preferable to use an organic solvent satisfying at least one of the following (A) and (B).
(A) The spontaneous ignition temperature is equal to that of PGMEA generally used for the substrate treatment, or closer to that of the acetic acid than PGMEA.
(B) At least one of the boiling point under the same process pressure, the vapor pressure under the same process temperature and the molecular weight is equal to that of PGMEA or closer to that of the acetic acid than PGMEA.

There can be many such organic solvents, and examples thereof include propylene glycol monomethyl ether (PGME), methyl isobutyl carbinol (MIBC), methyl isobutyl ketone (MIBK), butyl acetate (nBA), and γ-butyrolactone in addition to PGMEA. Organic solvents that meet the above requirements, such as sulfoxides, sulfones, lactams, polyhydric alcohols, dialkyl glycol ethers, alkylene glycol monoalkyl ethers, alkylene glycol esters, alkylene glycol monoalkyl ether acetates, ketones, lactic acid alkyl esters, other ethers and esters, aliphatic hydrocarbons, aromatic hydrocarbons, terpenes, etc. Other organic solvents that meet the above requirements such as ethers, esters, aliphatic hydrocarbons, aromatic hydrocarbons, terpenes, etc. may be used.

### Modification Examples

In the above example, the PEB treatment on the wafer W is performed by the thermal treatment apparatus 40. In place of this, the PEB treatment may be performed by the developing apparatus 30 if the temperature of the wafer W at the PEB treatment and the temperature of the wafer W at the development are almost the same. Specifically, for example, the preheating treatment at Step S7a may also serve as the PEB treatment.

Besides, the layer L1 including the developing apparatus 30 is stacked on the layer L2 including a coating film forming apparatus such as the resist coating apparatus in the above example. In other words, the developing apparatus 30 is provided in a region on the front side where the coating film forming apparatus is provided in plan view. In place of this, the developing apparatus may be provided in a region on the rear side where the thermal treatment apparatus 40 is provided in plan view. In this case, the developing apparatus 30 may be installed in a section having a size equal to a section where the thermal treatment apparatuses 40 is installed. Further, the layer L1 including the developing apparatus 30 may be stacked in either an upper or lower direction with respect to the layer L2 including the coating film forming apparatus such as the resist coating apparatus.

Though the delivery of the wafer W between the interface station 5 and the exposure apparatus 4 by the coating and developing system is explained in the above example, the coating and developing system does not need to be directly connected to the exposure apparatus. In this case, for example, after the wafer W is transferred from the cassette station 2 to the treatment station 3 and subjected to the necessary treatments, the wafer W is transferred again to the cassette station 2 for transfer to the outside. Besides, an unnecessary one of the various treatment apparatuses is not provided or a treatment in the unnecessary apparatus does not need to be performed.

In the above example, the portion formed of the nickel-chromium alloy or ceramic having corrosion resistance against acid may be the one subjected to a surface treatment on a surface in contact with acid or vapor of acid in a stainless base material if the surface treatment of applying the corrosion resistance is not difficult. For example, the members forming the side wall part 370 of the lower chamber 302, the first divided member 351 and the second divided member 352 of the top plate part 316, and the flow paths 541, 542, 543 in the vaporizer 501 may be the ones subjected to the surface treatment on surfaces in contact with acid or vapor of acid in the stainless base material.

The surface treatment of applying the corrosion resistance against acid is, for example, a treatment of covering the surface with a fluorocarbon resin having corrosion resistance against acid, and may be a passivation treatment.

Note that the vapor of acid is not in contact with the first divided member 351 of the top plate part 316 depending on the shapes of the second divided member 352 of the top plate part 316 and the gas supplier 310 in some cases. In this case, the first divided member 351 may be formed of a material not having corrosion resistance against acid.

Further, a casing (not illustrated) for collectively housing the chamber 300 and the hot plate 401 may be provided, a cover (not illustrated) covering the gap between the upper chamber 301 and the lower chamber 302 from the outside of the chamber 300 may be provided in the casing, and the inside of the cover may be exhausted. This can prevent an inner wall surface and so on of the casing from being contaminated with the sublimate from the metal-containing resist film.

As illustrated in FIG. 8, the heating part 400 may have a discharge port 430 which discharges an inert gas toward a central portion of a rear surface of the wafer W mounted on the mounting surface 401a of the hot plate 401. Then, during the development by the developing gas while heating the wafer W by the hot plate 401 (specifically, during the above Step S7b), the inert gas may be discharged from the discharge port 430 toward the central portion of the rear surface of the wafer W. This can prevent the sublimate from the metal-containing resist film from going around to the rear surface of the wafer W. Accordingly, it is possible to prevent the rear surface of the wafer W from being contaminated by the sublimate. Note that the inert gas discharged from the discharge port 430 may be the one heated outside the chamber 300 and outside the hot plate 401.

Note that to the discharge port 430, a gas supply mechanism (not illustrated) of the inert gas is connected. This gas supply mechanism has, for example, a supply equipment group including a supply source of the inert gas and an opening/closing valve and a flow regulating valve for controlling distribution of the inert gas.

The discharge port 430 is composed of, for example, a through hole 431 penetrating the central portion of the plate-shaped member 411, a through hole 432 penetrating the central portion of the plate-shaped member 412, and so on. An O-ring 440 having elasticity may be provided as a sealing member so as to seal a gap between the plate-shaped members 411 and 412 around the through holes 431, 432. The O-ring 440 is made of, for example, resin, specifically, made of a fluorocarbon resin.

Further, in the case where the inert gas is discharged from the discharge port 430 as above, the wafer W may be supported on the plurality of protrusions 420 protruding from the above-explained mounting surface 401a during the discharge. This can more uniformly form a gas flow of the inert gas from the center toward the periphery of the wafer W in the wafer circumferential direction between the rear surface of the wafer W and the mounting surface 401a. As a result, it is possible to more appropriately prevent the sublimate from the metal-containing resist film from going around to the rear surface of the wafer W.

Further, in the case of discharging the inert gas from the discharge port 430 during the development of wafer W supported on the plurality of protrusions 420 by the developing gas while heating the wafer W by the hot plate 401, a region (region R2 in the drawing) at an outermost circumference of the mounting surface 401a may be smaller in height of the protrusion 420 than a region (region R1 in the drawing) inside the region at the outermost circumference. This can prevent the flow of the inert gas from the center toward the periphery of the wafer W from being blocked by the protrusions 420 provided in the outermost circumference region. As a result, it is possible to more surely prevent the sublimate from the metal-containing resist film from going around to the rear surface of the wafer W, by the gas flow.

Note that at least the protrusion 420 provided in the region (region R1 in the drawing) inside the region at the outermost circumference among the protrusions 420 on the hot plate 401 provided in the developing apparatus 30 may be higher than the protrusions provided at the hot plate included in another treatment apparatus in the coating and developing system 1. The higher protrusions can prevent the wafer W from floating from the hot plate 401 even if the flow rate of the inert gas from the discharge port 430 is high, and can appropriately form the gas flow of the inert gas from the center toward the periphery of the wafer W.

In the case of discharging the inert gas from the discharge port 430 during the development of wafer W supported on the plurality of protrusions 420 by the developing gas while heating the wafer W by the hot plate 401, the heating may be performed in a state where a raising and lowering pin 450 as a raising and lowering member is in contact with the wafer W. This offers the following effect. That is, it is possible to prevent the wafer W from being displaced on the hot plate 401 due to the inert gas discharged from the discharge port 430, by the friction force between the raising and lowering pin 450 and the wafer W.

The raising and lowering pin 450 relays the wafer W when delivering the wafer W between a transfer apparatus outside the developing apparatus 30 and the hot plate 401, and rises and lowers with respect to the mounting surface 401a to deliver the wafer W to/from the plurality of protrusions 420. Three or more raising and lowering pins 450 are provided along the circumferential direction of the mounting surface 401a coinciding with the wafer circumferential direction. Each of the raising and lowering pins 450 is used inserted into an insertion hole 460 provided in a manner to penetrate the hot plate 401. The insertion hole 460 is composed of, for example, a through hole 461 penetrating the central portion of the plate-shaped member 411, a through hole 462 penetrating the central portion of the plate-shaped member 412, and so on. An O-ring 441 having elasticity may be provided as a sealing member so as to seal a gap between the plate-shaped members 411 and 412 around the through holes 461, 462. The O-ring 441 is made of, for example, resin, specifically, made of a fluorocarbon resin.

A contact portion of the raising and lowering pin 450 with the wafer W may be made of a fluorocarbon resin. If it is made of a fluorocarbon resin, it is possible to prevent the contact portion from being corroded by the acid in the developing gas and to increase the friction force between the raising and lowering pin 450 and the wafer W.

The raising and lowering pin 450 has, for example, a main body part 451 formed in a columnar shape (specifically, a cylindrical columnar shape) extending in the vertical direction, and a contact part 452 covering a tip of the main body part 451 and coming into contact with the rear surface of the wafer W as illustrated in FIG. 9. The contact part 452 is made of a fluorocarbon resin, whereas the main body part 451 is made of, for example, ceramic so that the main body part 451 has rigidity and corrosion resistance against acid.

The raising and lowering pin 450 may be supported by an elastic member 470 so as to apply an upward urging force to the raising and lowering pin 450. Specifically, the raising and lowering pin 450 may be supported by a raising and lowering mechanism 480 which raises and lowers the raising and lowering pin 450 via the elastic member 470.

In this case, the elastic modulus of the elastic member 470 and the height of the raising and lowering pin 450 at the development by the developing gas are set, for example, as follows. Specifically, the wafer W is supported by both of the raising and lowering pins 450 at the height and the protrusions 420, and the elastic modulus and the height are set so that the repulsive force acting on the wafer W from the elastic members 470 in that state becomes weaker than that when the wafer W is not supported by the protrusions 420 but only by the raising and lowering pins 450. In other words, the elastic modulus and the height are set so that the repulsive force acting on the wafer W from the elastic members 470 via all of the raising and lowering pins 450 becomes smaller than the gravity acting on the wafer W at the development when the wafer W is supported by both of the raising and lowering pins 450 at the above height and the protrusions 420.

The raising and lowering mechanism 480 has, for example, a support member 481 which supports the plurality of raising and lowering pins 450, and a driver (not illustrated) which generates a driving force for raising and lowering the support member 481. By raising and lowering the support member 481 by the driving force by the driver, the raising and lowering pins 450 are raised and lowered.

The support member 481 has a first support member 482 provided for each of the raising and lowering pins 450, and a second support member 483 which collectively support the first support members 482.

The first support member 482 is formed in a bottomed cylindrical shape and houses a lower portion of the raising and lowering pin 450. To a bottom portion of the first support member 482, a lower end of the elastic member 470 having an upper end connected to a lower end of the raising and lowering pin 450 is connected. Further, a side wall of the first support member 482 guides the raising and lowering of the raising and lowering pin 450.

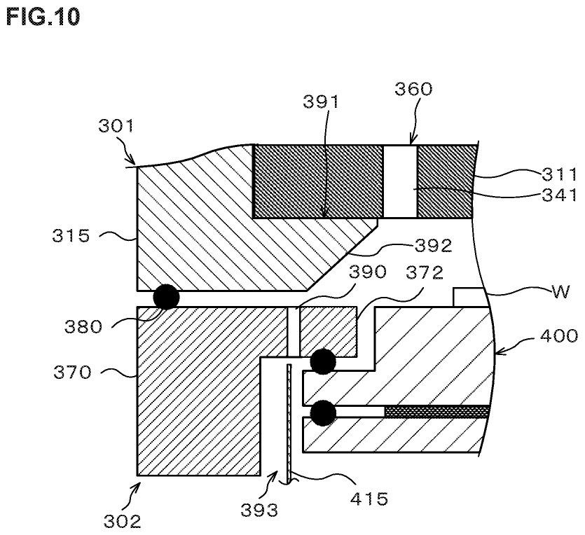

FIG. 10 is a view for explaining another example of the lower chamber 302.

The provision of the O-ring 380 which seals a gap between the side wall part 315, namely, the outer peripheral portion of the upper chamber 301 and the side wall part 370 of the lower chamber 302 can prevent the sublimate from the metal-containing resist film from leaking to the outside of the chamber 300 even when the pressure in the treatment space K1 becomes higher than the pressure outside the chamber 300 directly after the introduction of the developing gas to the treatment space K1 or the like.

However, the degree of flattening of the O-ring 380 does not become uniform in the wafer circumferential direction, so that a slight gap may occur between at least one of the upper chamber 301 and the lower chamber 302, and, the O-ring 380. Further, a slight gap may similarly occur due to a manufacturing tolerance of the O-ring 380. The gap is not uniformly formed in the wafer circumferential direction. Accordingly, the gas flow formed around the peripheral portion of the wafer W on the heating part 400 becomes non-uniform in the wafer circumferential direction due to the exhaust by the peripheral exhauster 360 performed so that the treatment space K1 becomes negative pressure at the development due to the influence of the gas entering the treatment space K1 through the gap depending on the treatment condition such as the exhaust rate by the peripheral exhauster 360. As a result, the development may become non-uniform in the wafer circumferential direction.

To prevent the above, as illustrated in FIG. 10, a plurality of gas supply ports 390 opening toward the gap may be provided along the wafer circumferential direction on the inner side than the O-ring 380 in plan view of the side wall part 370 of the lower chamber 302. Specifically, the plurality of gas supply ports 390 opening toward the gap may be provided along the wafer circumferential direction at the annular part 372 of the side wall part 370. Thus, when the exhaust by the peripheral exhauster 360 is performed, the atmosphere in the space below the annular part 372 is sucked into the gas supply ports 390 and discharged from the gas supply ports 390 toward the gap, and the discharged gas goes toward the through holes 341 as the exhaust ports of the peripheral exhauster 360. As a result, a gas flow from the gas supply ports 390 toward the exhaust ports is formed in the entire wafer circumferential direction. In other words, an air curtain is formed around the wafer W mounted on the heating part 400. Therefore, the gas is blocked by the air curtain even if flowing through the gap, so that it is possible to prevent the developing result from becoming non-uniform in the wafer circumferential direction due to the influence of the gas entering the chamber 300 through the gap. Further, since the gas outside the treatment space K1 is aggressively sucked from the gas supply ports 390, it is possible to reduce the amount of the gas outside the treatment space K1 toward the treatment space K1 through the gap. Therefore, it is possible to prevent the developing result from becoming non-uniform in the wafer circumferential direction due to the influence of the gas entering the treatment space K1 through the gap.

In the case of providing the gas supply port 390, an inner peripheral end portion of the side wall part 315, namely, the outer peripheral portion of the upper chamber 301 may be made a rectifier 391 which causes the gas from the gas supply port 390 to go toward the through hole 341. The rectifier 391 may be formed so that an inner peripheral end surface 392 of the rectifier 391 forms a straight line or a curved line concave upward linking the gas supply port 390 and the through hole 341 in cross-sectional view. This can form an air curtain higher in blocking property.

Besides, in the case of providing the gas supply port 390, an inner peripheral wall at a portion below the annular part 372 of the side wall part 370 of the lower chamber 302 and the hot plate 401 may be separated by a wall (specifically, a reflection plate 415 reflecting the heat of the hot plate 401 to the hot plate 401), and a gap may be provided between the wall and the hot plate 401. Further, a space formed by the inner peripheral wall and the wall may be made a gas supply path 393 leading to the gas supply port 390. In other words, the gas supply path 393 and the hot plate 401 may be separated by the wall. This can prevent the hot plate 401 from being cooled by the gas flowing through the gas supply path 393, and can efficiently heat the hot plate 401. Note that the reflection plate 415 is made of metal.

Stated differently, the O-ring 380 is intended to narrow or close the gap between the side wall part 370 and the side wall part 315 of the upper chamber 301, that is, a sealing member. In this embodiment, for example, a portion of the side wall part 370 in contact with the O-ring 380 and the annular part 372 are made of the same material and integrally provided. Note that the material mentioned here can be selected from various solid materials such as metal, resin, or ceramic. In the case where they are integrally provided, it can be considered that the heat received by the annular part 372 from the heating part 400 efficiently conducted to the contact portion and the O-ring 380 improves the sealing property of the O-ring 380 owing to the thermal expansion so that the outside air becomes difficult to enter the treatment space.

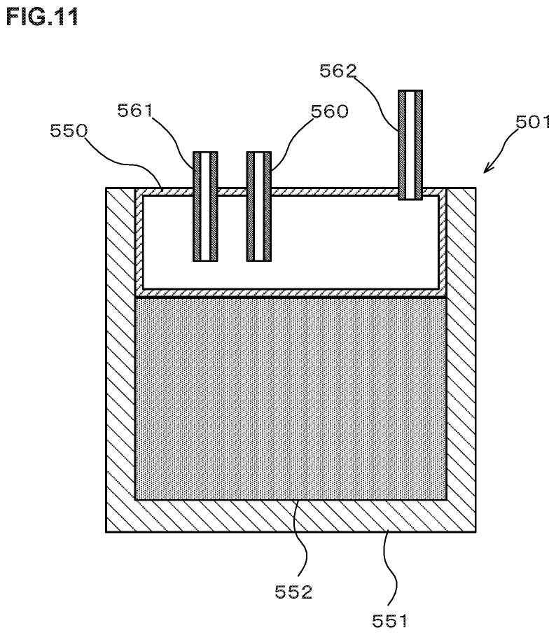

FIG. 11 is a view illustrating another example of the vaporizer 501. The vaporizer 501 in FIG. 11 is connected to the gas supplier 310 as with the vaporizer 501 in FIG. 5, specifically, connected to the gas supplier 310 via the supply path 502.

The vaporizer 501 in FIG. 11 has a housing chamber 550, a heating part 551, and a thermal mass part 552.

The housing chamber 550 houses a mixed solution of acid and another chemical (for example, an organic solvent) as a raw material of the developing gas. To the housing chamber 550, a solution supply path 560 which supplies the mixed solution to the housing chamber 550 and a carrier gas supply path 561 which supplies an inert gas as the carrier gas to the housing chamber 550 are connected. The inert gas supplied from the carrier gas supply path 561 may be used for bubbling of the mixed solution. Further, to the housing chamber 550, the supply path 502 which supplies the developing gas produced by vaporizing the solution of the raw material in the housing chamber 550 is connected.

The amount of the mixed solution housed at one time in the housing chamber 550 is enough for one time of the development by the developing gas.

The heating part 551 heats at least the housing chamber 550.

The thermal mass part 552 is provided adjacent to the housing chamber 550 and is heated together with the housing chamber 550 by the heating part 551. The thermal mass part 552 increases the thermal capacity of the whole portion to be heated by the heating part 551. The thermal mass part 552 is larger in volume than the housing chamber 550 (specifically, the housing space in the housing chamber 550).

The concentration of an acid gas in the developing gas produced by vaporizing the mixed solution being the raw material of the developing gas may depend on the temperature of the mixed solution. In this case, the provision of the thermal mass part 552 can prevent the housing chamber 550 from being cooled by the carrier gas and, as a result, to stabilize the temperature of the mixed solution as the raw material of the developing gas housed in the housing chamber 550. Accordingly, it is possible to stabilize the concentration of the acid in the developing gas supplied from the vaporizer 501.

The embodiments disclosed herein are examples in all respects and should not be considered to be restrictive. Various omissions, substitutions, and changes may be made in the embodiments without departing from the scope and spirit of the attached claims. For example, configuration requirements of the above embodiments can be arbitrarily combined. The operations and effects about the configuration requirements relating to a combination can be obtained as a matter of course from an arbitrary combination, and those skilled in the art can obtain obvious other operations and other effects from the description herein.

Further, the effects explained herein are merely explanatory or illustrative in all respects and not restrictive. The technique relating to this disclosure can offer obvious other effects to those skilled in the art from the description herein in addition to or in place of the above effects.

Note that the following configuration examples also belong to the technical scope of this disclosure.
(1) A developing apparatus for developing a substrate having a coating film of a metal-containing resist formed thereon, the developing apparatus including:
   a heating part configured to support and heat the substrate;
   a chamber configured to cover the heating part and form a treatment space above the heating part;
   a gas supplier to which a developing gas containing acid is supplied; and
   a dispersion mechanism configured to disperse the developing gas supplied to the gas supplier and discharge the developing gas to the treatment space from a plurality of discharge ports formed at positions above the heating part.
(2) The developing apparatus according to the (1), wherein
   the dispersion mechanism has:
      a downstream dispersion plate formed with the plurality of discharge ports; and
      an upstream dispersion plate provided above the downstream dispersion plate and forming a diffusion space between the upstream dispersion plate and the downstream dispersion plate, and formed with a plurality of relay holes, and
   discharges the developing gas supplied to the gas supplier and discharged from the plurality of relay holes to the diffusion space, from the plurality of discharge ports to the treatment space.
(3) The developing apparatus according to the (1) or (2), wherein
   the heating part has a hot plate having a mounting surface on which the substrate is mounted, and a heater pattern,
   the hot plate further having:
      plate-shaped members made of ceramic holding the heater pattern from top and bottom, and one of the plate-shaped members having the mounting surface; and
      a sealing member configured to seal a gap between the plate-shaped members at an outer periphery of the heater pattern.
(4) The developing apparatus according to the (2), further including
   a peripheral exhauster configured to exhaust the treatment space from a peripheral edge portion side of the substrate supported on the heating part in plan view, wherein:
   the peripheral exhauster has:
      an exhaust port opening to the treatment space; and
      a peripheral exhaust path extending from the exhaust port;
   the dispersion mechanism further has an intermediate member located between the downstream dispersion plate and the upstream dispersion plate and forming the diffusion space together with the downstream dispersion plate and the upstream dispersion plate; and
   the intermediate member forms a part of the peripheral exhaust path.
(5) The developing apparatus according to the any one of the (1) to (3), further including
   a peripheral exhauster configured to exhaust the treatment space from a peripheral edge portion side of the substrate supported on the heating part in plan view, wherein:
   the peripheral exhauster has an exhaust port opening to the treatment space;
   the chamber has:
      an upper chamber having the dispersion mechanism; and
      a lower chamber forming the treatment space together with the upper chamber; and
   an inner peripheral end of a joint between the upper chamber and the lower chamber at an outer periphery of the treatment space is located on a lower side than the exhaust port of the peripheral exhauster.
(6) The developing apparatus according to the (2), further including
   a peripheral exhauster configured to exhaust the treatment space from a peripheral edge portion side of the substrate supported on the heating part in plan view, wherein:
   the peripheral exhauster has:
      an exhaust port opening to the treatment space; and
      a peripheral exhaust path extending from the exhaust port;
   the chamber has:
      a top plate part located above the upstream dispersion plate; and
      a heater configured to heat the top plate part; and
   the top plate part is in contact with the gas supplier and the peripheral exhaust path.
(7) The developing apparatus according to the (2), (4) or (6), wherein:
   the chamber has:
      an upper chamber having the dispersion mechanism; and
      a lower chamber forming the treatment space together with the upper chamber;
   the upper chamber has an upper side wall part provided with a supporter which supports outer peripheral portions of the downstream dispersion plate and the upstream dispersion plate, an inner peripheral surface of the supporter being exposed to the treatment space;
   the lower chamber has a lower side wall part which covers an outer peripheral portion of the heating part and faces the upper side wall part; and
   the downstream dispersion plate, the upstream dispersion plate, the upper side wall part, and the lower side wall part are formed of silicon, a silicon compound, or a nickel-chromium alloy.
(8) The developing apparatus according to the any one of the (1) to (7), further including:
   a supply path having one end connected to the gas supplier and another end connected to a vaporizer;
   a branch path connected to the supply path; and
   a controller,
   the controller being configured to perform a control to execute: preheating the substrate before development; and heating the substrate supported on the heating part and discharging the developing gas supplied from the vaporizer via the supply path, to the treatment space to develop the substrate, wherein
   the developing gas is supplied from the vaporizer in the preheating, in which the developing gas supplied from the vaporizer is not made to flow to the gas supplier but is made to flow to the branch path.
(9) The developing apparatus according to the any one of the (1) to (8), further including
   a supply path having one end connected to the gas supplier and another end connected to a vaporizer, wherein
   an inner wall surface of a flow path of the acid or vapor of the acid in the vaporizer is formed of silicon, a silicon compound, or a nickel-chromium alloy.
(10) A substrate treatment system including:
   a plurality of layers each including a treatment apparatus stacked in a vertical direction, wherein
   the plurality of stacked layers have:
      a plurality of layers each including the developing apparatus according to any one of the (1) to (9); and
      a height of 2.8 meters or less.
(11) The developing apparatus according to any one of the (1) to (10), wherein:
   the heating part has:
      a hot plate having a mounting surface on which the substrate is mounted;
      a discharge port configured to discharge an inert gas from the mounting surface toward a central portion of the substrate mounted on the mounting surface;
      a plurality of protrusions provided in a manner to protrude from the mounting surface of the hot plate and configured to support the substrate; and
      a raising and lowering member configured to be able to support the substrate and rising and lowering with respect to the mounting surface to deliver the substrate to/from the plurality of protrusions; and
   the heating of the substrate supported on the plurality of protrusions by the hot plate is performed in a state where the raising and lowering member is in contact with the substrate.
(12) The developing apparatus according to any one of the (1) to (11), wherein
   the heating part has:
      a hot plate having a mounting surface on which the substrate is mounted;
      a protrusion protruding from the mounting surface of the hot plate; and
      a discharge port configured to discharge an inert gas from the mounting surface toward a central portion of the substrate mounted on the mounting surface;
   the mounting surface is partitioned into a plurality of regions along a radial direction of the mounting surface;
   the protrusion is provided in each of the regions; and
   the region at an outermost circumference is smaller in height of the protrusion than the region inside the region at the outermost circumference.
(13) The developing apparatus according to any one of the (1) to (12), further including
   a peripheral exhauster configured to exhaust the treatment space from a peripheral edge portion side of the substrate supported on the heating part in plan view, wherein:
   the peripheral exhauster has a plurality of exhaust ports opening to the treatment space, along a circumferential direction of the substrate supported on the heating part;
   the chamber has:
      an upper chamber having the dispersion mechanism; and
      a lower chamber forming the treatment space together with the upper chamber;
   the lower chamber has:
      a lower side wall part which covers an outer peripheral portion of the heating part and faces an outer peripheral portion of the upper chamber; and
      a sealing member configured to seal a gap between the outer peripheral portion of the upper chamber and the lower side wall part; and
   the lower side wall part has a plurality of gas supply ports opening toward the gap, along the circumferential direction of the substrate supported on the heating part on an inner side than the sealing member in plan view.
(14) The developing apparatus according to any one of the (1) to (13), further including
   a vaporizer connected to the gas supplier, wherein
   the vaporizer has:
      a housing chamber configured to house a mixed solution of the acid and another chemical as a raw material of the developing gas;
      another heating part configured to heat the housing chamber; and
      a thermal mass part provided adjacent to the housing chamber, heated together with the housing chamber by the other heating part, and larger in volume than the housing chamber.
(15) A developing method of developing a substrate having a coating film of a metal-containing resist formed thereon, the developing method including
   heating the substrate supported on a heating part, and discharging a developing gas containing acid to a treatment space above the heating part to develop the substrate, wherein
   in the developing, the developing gas supplied to a gas supplier is dispersed and discharged to the treatment space from a plurality of discharge ports formed at positions above the heating part.

According to this disclosure, it is possible to obtain an excellent pattern of a metal-containing resist.

What is claimed is:

1. A developing apparatus for developing a substrate having a coating film of a metal-containing resist formed thereon, the developing apparatus comprising:
a heating part configured to support and heat the substrate;
a chamber configured to cover the heating part and form a treatment space above the heating part;
a gas supplier to which a developing gas containing acid is supplied; and
a dispersion mechanism configured to disperse the developing gas supplied to the gas supplier and discharge the developing gas to the treatment space from a plurality of discharge ports formed at positions above the heating part.

2. The developing apparatus according to claim 1, wherein
the dispersion mechanism has:
a downstream dispersion plate formed with the plurality of discharge ports; and
an upstream dispersion plate provided above the downstream dispersion plate and forming a diffusion space between the upstream dispersion plate and the downstream dispersion plate, and formed with a plurality of relay holes, and
discharges the developing gas supplied to the gas supplier and discharged from the plurality of relay holes to the diffusion space, from the plurality of discharge ports to the treatment space.

3. The developing apparatus according to claim 1, wherein
the heating part has a hot plate having a mounting surface on which the substrate is mounted, and a heater pattern,
the hot plate further having:
plate-shaped members made of ceramic holding the heater pattern from top and bottom, and one of the plate-shaped members having the mounting surface; and
a sealing member configured to seal a gap between the plate-shaped members at an outer periphery of the heater pattern.

4. The developing apparatus according to claim 2, further comprising
a peripheral exhauster configured to exhaust the treatment space from a peripheral edge portion side of the substrate supported on the heating part in plan view, wherein:
the peripheral exhauster has:
an exhaust port opening to the treatment space; and
a peripheral exhaust path extending from the exhaust port;
the dispersion mechanism further has an intermediate member located between the downstream dispersion plate and the upstream dispersion plate and forming the diffusion space together with the downstream dispersion plate and the upstream dispersion plate; and
the intermediate member forms a part of the peripheral exhaust path.

5. The developing apparatus according to claim 1, further comprising
a peripheral exhauster configured to exhaust the treatment space from a peripheral edge portion side of the substrate supported on the heating part in plan view, wherein:
the peripheral exhauster has an exhaust port opening to the treatment space;
the chamber has:
an upper chamber having the dispersion mechanism; and
a lower chamber forming the treatment space together with the upper chamber; and
an inner peripheral end of a joint between the upper chamber and the lower chamber at an outer periphery of the treatment space is located on a lower side than the exhaust port of the peripheral exhauster.

6. The developing apparatus according to claim 2, further comprising
a peripheral exhauster configured to exhaust the treatment space from a peripheral edge portion side of the substrate supported on the heating part in plan view, wherein:
the peripheral exhauster has:
an exhaust port opening to the treatment space; and
a peripheral exhaust path extending from the exhaust port;
the chamber has:
a top plate part located above the upstream dispersion plate; and
a heater configured to heat the top plate part; and
the top plate part is in contact with the gas supplier and the peripheral exhaust path.

7. The developing apparatus according to claim 2, wherein:
the chamber has:
an upper chamber having the dispersion mechanism; and
a lower chamber forming the treatment space together with the upper chamber;
the upper chamber has an upper side wall part provided with a supporter which supports outer peripheral portions of the downstream dispersion plate and the upstream dispersion plate, an inner peripheral surface of the supporter being exposed to the treatment space;
the lower chamber has a lower side wall part which covers an outer peripheral portion of the heating part and faces the upper side wall part; and
the downstream dispersion plate, the upstream dispersion plate, the upper side wall part, and the lower side wall part are formed of silicon, a silicon compound, or a nickel-chromium alloy.

8. The developing apparatus according to claim 1, further comprising:
a supply path having one end connected to the gas supplier and another end connected to a vaporizer;
a branch path connected to the supply path; and
a controller,
the controller being configured to perform a control to execute: preheating the substrate before development; and heating the substrate supported on the heating part and discharging the developing gas supplied from the vaporizer via the supply path, to the treatment space to develop the substrate, wherein
the developing gas is supplied from the vaporizer in the preheating, in which the developing gas supplied from the vaporizer is not made to flow to the gas supplier but is made to flow to the branch path.

9. The developing apparatus according to claim 1, further comprising
a supply path having one end connected to the gas supplier and another end connected to a vaporizer, wherein
an inner wall surface of a flow path of the acid or vapor of the acid in the vaporizer is formed of silicon, a silicon compound, or a nickel-chromium alloy.

10. A substrate treatment system comprising
a plurality of layers each including a treatment apparatus stacked in a vertical direction, wherein
the plurality of stacked layers have:
a plurality of layers each including the developing apparatus according to claim 1; and
a height of 2.8 meters or less.

11. The developing apparatus according to claim 1, wherein:
the heating part has:
a hot plate having a mounting surface on which the substrate is mounted;
a discharge port configured to discharge an inert gas from the mounting surface toward a central portion of the substrate mounted on the mounting surface;
a plurality of protrusions provided in a manner to protrude from the mounting surface of the hot plate and configured to support the substrate; and
a raising and lowering member configured to be able to support the substrate and rising and lowering with respect to the mounting surface to deliver the substrate to/from the plurality of protrusions; and
the heating of the substrate supported on the plurality of protrusions by the hot plate is performed in a state where the raising and lowering member is in contact with the substrate.

12. The developing apparatus according to claim 1, wherein
the heating part has:
a hot plate having a mounting surface on which the substrate is mounted;
a protrusion protruding from the mounting surface of the hot plate; and
a discharge port configured to discharge an inert gas from the mounting surface toward a central portion of the substrate mounted on the mounting surface;
the mounting surface is partitioned into a plurality of regions along a radial direction of the mounting surface;
the protrusion is provided in each of the regions; and
the region at an outermost circumference is smaller in height of the protrusion than the region inside the region at the outermost circumference.

13. The developing apparatus according to claim 1, further comprising
a peripheral exhauster configured to exhaust the treatment space from a peripheral edge portion side of the substrate supported on the heating part in plan view, wherein:
the peripheral exhauster has a plurality of exhaust ports opening to the treatment space, along a circumferential direction of the substrate supported on the heating part;
the chamber has:
an upper chamber having the dispersion mechanism; and
a lower chamber forming the treatment space together with the upper chamber;
the lower chamber has:
a lower side wall part which covers an outer peripheral portion of the heating part and faces an outer peripheral portion of the upper chamber; and
a sealing member configured to seal a gap between the outer peripheral portion of the upper chamber and the lower side wall part; and
the lower side wall part has a plurality of gas supply ports opening toward the gap, along the circumferential direction of the substrate supported on the heating part on an inner side than the sealing member in plan view.

14. The developing apparatus according to claim 1, further comprising
a vaporizer connected to the gas supplier, wherein
the vaporizer has:
a housing chamber configured to house a mixed solution of the acid and another chemical as a raw material of the developing gas;
another heating part configured to heat the housing chamber; and
a thermal mass part provided adjacent to the housing chamber, heated together with the housing chamber by the other heating part, and larger in volume than the housing chamber.

15. A developing method of developing a substrate having a coating film of a metal-containing resist formed thereon, the developing method comprising
heating the substrate supported on a heating part, and discharging a developing gas containing acid to a treatment space above the heating part to develop the substrate, wherein
in the developing, the developing gas supplied to a gas supplier is dispersed and discharged to the treatment space from a plurality of discharge ports formed at positions above the heating part.
